(19) United States
(12) Patent Application Publication
(10) Pub. No.: US 2026/0128721 A1
(43) Pub. Date: May 7, 2026

(54) ACOUSTIC WAVE DEVICE

(71) Applicant: Murata Manufacturing Co., Ltd., Nagaokakyo-shi (JP)

(72) Inventor: Katsuhito KURODA, Nagaokakyo-shi (JP)

(21) Appl. No.: 19/441,005

(22) Filed: Jan. 6, 2026

Related U.S. Application Data
(63) Continuation of application No. PCT/JP2024/025102, filed on Jul. 11, 2024.

(30) Foreign Application Priority Data
Sep. 5, 2023 (JP) 2023-143875

(51) Int. Cl. H03H 9/02; H03H 9/05; H03H 9/13; H03H 9/19

(52) U.S. Cl. CPC H03H 9/02015; H03H 9/0504; H03H 9/132; H03H 9/19

(57) ABSTRACT

An acoustic wave device includes a resonator including a piezoelectric layer including first and second main surfaces opposed to each other, an upper electrode on the first main surface of the piezoelectric layer, and a lower electrode on the second main surface of the piezoelectric layer, and a capacitor including an upper interdigital transducer (IDT) electrode on the first main surface of the piezoelectric layer, and a lower IDT electrode on the second main surface of the piezoelectric layer. The capacitor is connected in parallel with the resonator. The upper IDT electrode and the lower IDT electrode of the capacitor are electrically connected to one another.

### CROSS REFERENCE TO RELATED APPLICATIONS

This application claims the benefit of priority to Japanese Patent Application No. 2023-143875 filed on Sep. 5, 2023 and is a Continuation Application of PCT Application No. PCT/JP2024/025102 filed on Jul. 11, 2024. The entire contents of each application are hereby incorporated herein by reference.

### BACKGROUND OF THE INVENTION

### 1. Field of the Invention

The present invention relates to acoustic wave devices.

### 2. Description of the Related Art

U.S. Patent Application Publication No. 2019/0273478 discloses an acoustic wave device including a bulk acoustic wave (BAW) element utilizing a bulk wave. The acoustic wave device in U.S. Patent Application Publication No. 2019/0273478 includes a Lamb-wave loop circuit that generates an anti-phase to a target signal at a particular frequency, and the Lamb-wave loop circuit includes an IDT electrode.

Such an acoustic wave device is required to have a reduced size and to favorably adjust bandpass characteristics. In U.S. Patent Application Publication No. 2019/0273478, the IDT electrode included in the Lamb-wave loop circuit is provided for Lamb-wave excitation, and formation of a desired electrostatic capacitance by the IDT electrode included in the Lamb-wave loop circuit is not considered.

### SUMMARY OF THE INVENTION

Example embodiments of the present invention provide acoustic wave devices each with a reduced size and improved bandpass characteristics.

An acoustic wave device according to an example embodiment of the present invention includes a resonator including a piezoelectric layer including a first main surface and a second main surface opposite to the first main surface, an upper electrode on the first main surface of the piezoelectric layer, and a lower electrode on the second main surface of the piezoelectric layer, and a capacitor including an upper interdigital transducer (IDT) electrode on the first main surface of the piezoelectric layer, and a lower IDT electrode on the second main surface of the piezoelectric layer. The capacitor is connected in parallel with the resonator. The upper IDT electrode and the lower IDT electrode of the capacitor are electrically connected to one another.

Acoustic wave devices according to example embodiments of the present invention each have a reduced size and improved bandpass characteristics.

The above and other elements, features, steps, characteristics and advantages of the present invention will become more apparent from the following detailed description of the example embodiments with reference to the attached drawings.

### BRIEF DESCRIPTION OF THE DRAWINGS

FIG. 1 is a perspective view of an acoustic wave device according to a first example embodiment of the present invention.

FIG. 2 is a sectional view taken along line II-II′ in FIG. 1.

FIG. 3 is an explanatory diagram illustrating capacitances generated in a capacitor according to the first example embodiment of the present invention.

FIG. 4 is a sectional view of an acoustic wave device according to a second example embodiment of the present invention.

FIG. 5 is an explanatory diagram illustrating capacitances generated in a capacitor according to the second example embodiment of the present invention.

FIG. 6 is a circuit diagram illustrating an acoustic wave device according to a third example embodiment of the present invention.

FIG. 7 is a graph illustrating bandpass characteristics of acoustic wave devices according to Example 1 and Comparative Examples 1 and 2.

FIG. 8 is a circuit diagram illustrating an acoustic wave device according to a fourth example embodiment of the present invention.

FIG. 9 is a graph illustrating bandpass characteristics of acoustic wave devices according to Example 2 of an example embodiment of the present invention and Comparative Examples 1 and 3.

### DETAILED DESCRIPTION OF THE EXAMPLE EMBODIMENTS

Hereinafter, example embodiments of the present invention will be described in detail with reference to the drawings. The present invention is not limited to these example embodiments. Each example embodiment described in the present disclosure is illustrative, and configurations of different example embodiments can be partially replaced or combined with one another. In a modification and a second example embodiment and thereafter, description of matters in common with a first example embodiment will be omitted, and only different points will be described. Particularly, the same or similar operations and advantageous effects provided by similar configurations will not be described individually in each example embodiment.

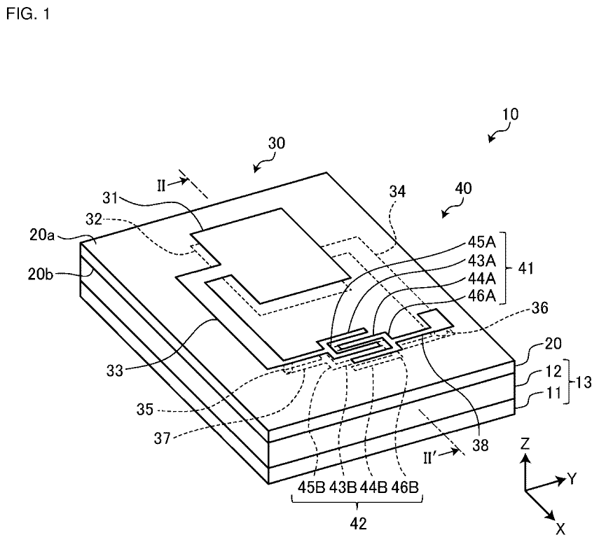

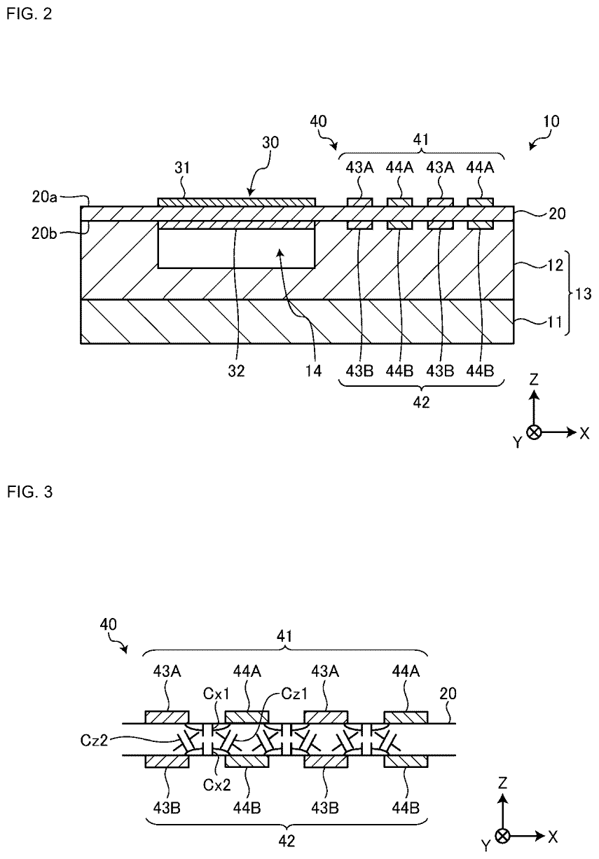

FIG. 1 is a perspective view of an acoustic wave device according to a first example embodiment of the present invention. FIG. 2 is a sectional view taken along line II-II′ in FIG. 1. As illustrated in FIGS. 1 and 2, an acoustic wave device 10 includes a support 13, a piezoelectric layer 20, a resonator 30, and a capacitor 40. The resonator 30 utilizes a bulk wave, that is, a bulk acoustic wave (BAW) element, for example. The capacitor 40 includes an interdigital transducer (IDT) electrode.

The following description is provided assuming that a thickness direction of the piezoelectric layer 20 is a Z-direction, a direction orthogonal or substantially orthogonal to the Z-direction is an X-direction, and a direction orthogonal or substantially orthogonal to the Z-direction and the X-direction is a Y-direction. Each of the X-direction and the Y-direction is a direction parallel or substantially parallel to a surface (a first main surface 20a) of the piezoelectric layer 20. Moreover, in the following description, a plan view indicates a positional relationship when seen in a direction (the Z-direction) perpendicular or substantially perpendicular to the first main surface 20a of the piezoelectric layer 20.

The support 13 is opposed to a second main surface 20b of the piezoelectric layer 20. The support 13 includes a support substrate 11 and an insulation layer 12. The support substrate 11 is made of silicon (Si), crystal, or the like, for example. The insulation layer 12 is provided between the support substrate 11 and the piezoelectric layer 20. The insulation layer 12 is made of an insulating material, such as silicon oxide, for example. The support 13 does not necessarily include the insulation layer 12, and the piezoelectric layer 20 may be provided on the support substrate 11. An adhesion layer, such as Ti, NiCr, or the like, for example, may be provided between a lower electrode 32 and the insulation layer 12.

As illustrated in FIG. 2, the support 13 (the insulation layer 12) includes a cavity portion 14 (hollow portion) provided at a surface opposed to the second main surface 20b of the piezoelectric layer 20. The cavity portion 14 is provided to overlap an excitation region of the resonator 30 including the piezoelectric layer 20, an upper electrode 31, and the lower electrode 32 overlapping one another in plan view. Therefore, a bulk wave is reflected by the cavity portion 14.

The piezoelectric layer 20 has a flat plate shape including the first main surface 20a and the second main surface 20b opposite to the first main surface 20a. The piezoelectric layer 20 is a substrate made of, for example, a single crystal of lithium niobate (LiNbO₃) or lithium tantalate (LiTaO₃). The thickness of the piezoelectric layer 20 is preferably, but not limited to, about 1 μm or less, for example.

As illustrated in FIGS. 1 and 2, the resonator 30 includes the piezoelectric layer 20, the upper electrode 31 provided to the first main surface 20a of the piezoelectric layer 20, and the lower electrode 32 provided to the second main surface 20b of the piezoelectric layer 20. The resonator 30 includes the lower electrode 32, the piezoelectric layer 20, and the upper electrode 31 being stacked on the support 13 in this order.

The resonator 30 has a membrane structure including the cavity portion 14 (hollow portion) on the second main surface 20b side of the piezoelectric layer 20. As illustrated in FIG. 2, in the region overlapping the cavity portion 14, the piezoelectric layer 20 is disposed between the upper electrode 31 and the lower electrode 32 in the Z-direction. Therefore, a bulk wave is conveyed between the upper electrode 31 and the lower electrode 32.

Each of the upper electrode 31 and the lower electrode 32 is made of metal, such as, for example, aluminum (Al), platinum (Pt), copper (Cu), tungsten (W), or molybdenum (Mo), or an alloy including at least one of these materials. Each of the upper electrode 31 and the lower electrode 32 may be a multilayer film.

As illustrated in FIG. 1, each of the upper electrode 31 and the lower electrode 32 is has a rectangular or substantially rectangular shape in plan view. However, each of the upper electrode 31 and the lower electrode 32 is not limited to such a shape and may have another shape, such as a circular shape, or a polygonal shape.

The capacitor 40 includes an upper IDT electrode 41 provided on the first main surface 20a of the piezoelectric layer 20 and a lower IDT electrode 42 provided on the second main surface 20b of the piezoelectric layer 20. The upper IDT electrode 41 is provided on the same layer as the upper electrode 31 included in the resonator 30. Moreover, the lower IDT electrode 42 is provided on the same layer as the lower electrode 32 included in the resonator 30.

The upper IDT electrode 41 and the lower IDT electrode 42 are electrically connected to one another through a first via 35 and a second via 36 provided so as to penetrate the piezoelectric layer 20. Moreover, the capacitor 40 is connected in parallel with the resonator 30. That is, one end of the capacitor 40 is connected to the upper electrode 31 through connection wiring 33. Further, the other end of the capacitor 40 is connected to the lower electrode 32 through connection wiring 34.

More specifically, the upper IDT electrode 41 includes a first electrode finger 43A, a second electrode finger 44A, a first busbar electrode 45A, and a second busbar electrode 46A. The plurality of first electrode fingers 43A extend in the Y-direction and one ends thereof in the extending direction are connected to the first busbar electrode 45A. The plurality of second electrode fingers 44A extend in the Y-direction and the other ends thereof in the extending direction are connected to the second busbar electrode 46A. The plurality of first electrode fingers 43A and the plurality of second electrode fingers 44A are arranged in an alternating manner in the X-direction with a gap therebetween. The first busbar electrode 45A and the second busbar electrode 46A extend in the X-direction and are disposed separately from one another in the Y-direction. The plurality of first electrode fingers 43A and the plurality of second electrode fingers 44A are arranged between the first busbar electrode 45A and the second busbar electrode 46A.

The lower IDT electrode 42 includes a third electrode finger 43B, a fourth electrode finger 44B, a third busbar electrode 45B, and a fourth busbar electrode 46B. The plurality of third electrode fingers 43B extend in the Y-direction and one ends thereof in the extending direction are connected to the third busbar electrode 45B. The plurality of fourth electrode fingers 44B extend in the Y-direction and the other ends thereof in the extending direction are connected to the fourth busbar electrode 46B. The plurality of third electrode fingers 43B and the plurality of fourth electrode fingers 44B are arranged in an alternating manner in the X-direction with a gap therebetween. The third busbar electrode 45B and the fourth busbar electrode 46B extend in the X-direction and are disposed separately from one another in the Y-direction. The plurality of third electrode fingers 43B and the plurality of fourth electrode fingers 44B are arranged between the third busbar electrode 45B and the fourth busbar electrode 46B.

In the present example embodiment, the plurality of first electrode fingers 43A of the upper IDT electrode 41 overlap the plurality of third electrode fingers 43B of the lower IDT electrode 42 and extend in the same direction as the extending direction of the plurality of third electrode fingers 43B. The plurality of second electrode fingers 44A of the upper IDT electrode 41 overlap the plurality of fourth electrode fingers 44B of the lower IDT electrode 42 and extend in the same direction as the extending direction of the plurality of fourth electrode fingers 44B.

In the following description, the first electrode finger 43A, the second electrode finger 44A, the third electrode finger 43B, and the fourth electrode finger 44B may simply be referred to as an electrode finger unless differences therebetween are unnecessary. Moreover, the first busbar electrode 45A, the second busbar electrode 46A, the third busbar electrode 45B, and the fourth busbar electrode 46B may simply be referred to as a busbar electrode unless differences therebetween are unnecessary.

One end of the connection wiring 33 provided on the first main surface 20a of the piezoelectric layer 20 is connected to the upper electrode 31, and the other end of the connection wiring 33 is connected to the first busbar electrode 45A. Moreover, one end of the connection wiring 37 provided on the second main surface 20b of the piezoelectric layer 20 is connected to the connection wiring 33 through the first via 35. The other end of the connection wiring 37 is connected to the third busbar electrode 45B.

Therefore, the first electrode finger 43A of the upper IDT electrode 41 and the third electrode finger 43B of the lower IDT electrode 42 are electrically connected to one another through the connection wiring 33, the first via 35, and the connection wiring 37. Moreover, the plurality of first electrode fingers 43A of the upper IDT electrode 41 and the plurality of third electrode fingers 43B of the lower IDT electrode 42 are electrically connected to the upper electrode 31 of the resonator 30 through the connection wiring 33, the first via 35, and the connection wiring 37. Therefore, the same electric potential is supplied to the first electrode finger 43A of the upper IDT electrode 41 and the third electrode finger 43B of the lower IDT electrode 42.

Similarly, one end of the connection wiring 34 provided on the second main surface 20b of the piezoelectric layer 20 is connected to the lower electrode 32, and the other end of the connection wiring 34 is connected to the fourth busbar electrode 46B. Moreover, one end of the connection wiring 38 provided on the first main surface 20a of the piezoelectric layer 20 is connected to the connection wiring 34 through the second via 36. The other end of the connection wiring 38 is connected to the second busbar electrode 46A.

Therefore, the second electrode finger 44A of the upper IDT electrode 41 and the fourth electrode finger 44B of the lower IDT electrode 42 are electrically connected to one another through the connection wiring 34, the second via 36, and the connection wiring 38. Moreover, the plurality of second electrode fingers 44A of the upper IDT electrode 41 and the plurality of fourth electrode fingers 44B of the lower IDT electrode 42 are electrically connected to the lower electrode 32 of the resonator 30 through the connection wiring 34, the second via 36, and the connection wiring 38. Therefore, the same electric potential is supplied to the second electrode finger 44A of the upper IDT electrode 41 and the fourth electrode finger 44B of the lower IDT electrode 42. Furthermore, the electric potential supplied to the first electrode finger 43A of the upper IDT electrode 41 and the third electrode finger 43B of the lower IDT electrode 42 and the electric potential supplied to the second electrode finger 44A of the upper IDT electrode 41 and the fourth electrode finger 44B of the lower IDT electrode 42 are different from one another.

The connecting relationship of the upper IDT electrode 41 and the lower IDT electrode 42 of the capacitor 40 with respect to the upper electrode 31 and the lower electrode 32 of the resonator 30 is not limited to the configuration described above. The plurality of first electrode fingers 43A of the upper IDT electrode 41 and the plurality of third electrode fingers 43B of the lower IDT electrode 42 may be electrically connected to the lower electrode 32 of the resonator 30, and the plurality of second electrode fingers 44A of the upper IDT electrode 41 and the plurality of fourth electrode fingers 44B of the lower IDT electrode 42 may be electrically connected to the upper electrode 31 of the resonator 30.

As illustrated in FIG. 2, the plurality of first electrode fingers 43A of the upper IDT electrode 41 and the plurality of third electrode fingers 43B of the lower IDT electrode 42 are electrically connected to one another and are opposed to one another with the piezoelectric layer 20 interposed therebetween in the Z-direction. As described above, the same electric potential is supplied to the plurality of first electrode fingers 43A of the upper IDT electrode 41 and the plurality of third electrode fingers 43B of the lower IDT electrode 42 opposed to one another in the Z-direction.

The plurality of second electrode fingers 44A of the upper IDT electrode 41 and the plurality of fourth electrode fingers 44B of the lower IDT electrode 42 are electrically connected to one another and are opposed to one another with the piezoelectric layer 20 interposed therebetween in the Z-direction. As described above, the same electric potential is supplied to the plurality of second electrode fingers 44A of the upper IDT electrode 41 and the plurality of fourth electrode fingers 44B of the lower IDT electrode 42 opposed to one another in the Z-direction. Furthermore, different electric potentials are supplied to the plurality of first electrode fingers 43A and the plurality of second electrode fingers 44A of the upper IDT electrode 41 adjacent to one another in the X-direction. Different electric potentials are supplied to the plurality of third electrode fingers 43B and the plurality of fourth electrode fingers 44B of the lower IDT electrode 42.

FIG. 3 is an explanatory diagram illustrating capacitances generated in a capacitor according to the first example embodiment. As illustrated in FIG. 3, in the capacitor 40, a capacitance Cx1 is generated between the first electrode finger 43A and the second electrode finger 44A of the upper IDT electrode 41 adjacent to one another in the X-direction in the same layer. Moreover, a capacitance Cx2 is generated between the third electrode finger 43B and the fourth electrode finger 44B of the lower IDT electrode 42 adjacent to one another in the X-direction in the same layer. Further, a capacitance Cz1 is generated between the first electrode finger 43A of the upper IDT electrode 41 and the fourth electrode finger 44B of the lower IDT electrode 42 positioned diagonally with the piezoelectric layer 20 interposed therebetween. Moreover, a capacitance Cz2 is generated between the second electrode finger 44A of the upper IDT electrode 41 and the third electrode finger 43B of the lower IDT electrode 42 positioned diagonally with the piezoelectric layer 20 interposed therebetween.

Therefore, the capacitor 40 includes the upper IDT electrode 41 and the lower IDT electrode 42 disposed with the piezoelectric layer 20 interposed therebetween, and thus the capacitance of the capacitor 40 as a whole can be larger than that in a configuration in which only one of the upper IDT electrode 41 and the lower IDT electrode 42 is provided. Alternatively, a size (a planar area) of the capacitor 40 to generate the same capacitance can be reduced as compared with the case in which only one of the upper IDT electrode 41 and the lower IDT electrode 42 is provided.

The capacitor 40 is connected to the resonator 30, and thus an attenuation pole frequency of the resonator 30 is appropriately adjustable. Therefore, the acoustic wave device 10 can have a reduced size and favorably adjust bandpass characteristics. The bandpass characteristics of the resonator 30 will be described later in a third example embodiment and a fourth example embodiment of the present invention.

In FIGS. 1 to 3, in order to make the drawings easier to see, the first electrode finger 43A and the second electrode finger 44A of the upper IDT electrode 41 and the third electrode finger 43B and the fourth electrode finger 44B of the lower IDT electrode 42 are each illustrated to include two electrode fingers. However, the number of each type of electrode fingers is not limited to this, but may be three or more, for example. The width of each electrode finger and the arrangement pitch are merely illustration and may be changed as appropriate in accordance with the capacitance and the size (a planar area) required for the capacitor 40.

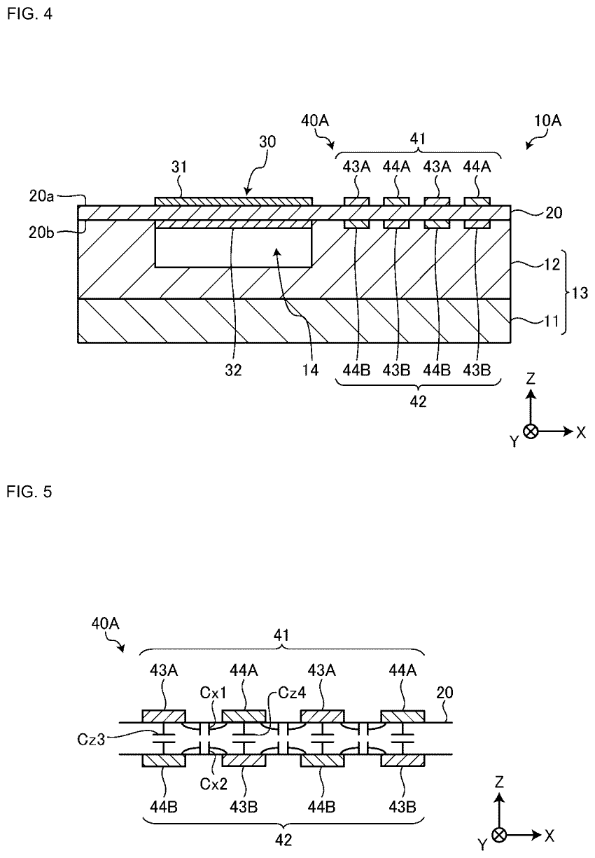

FIG. 4 is a sectional view of an acoustic wave device according to a second example embodiment of the present invention. As illustrated in FIG. 4, in an acoustic wave device 10A according to the second example embodiment, a positional relationship of the first electrode finger 43A and the second electrode finger 44A of the upper IDT electrode 41 with respect to the third electrode finger 43B and the fourth electrode finger 44B of the lower IDT electrode 42 is different from that in the first example embodiment described above. A connecting relationship of each electrode finger of the upper IDT electrode 41 and each electrode finger of the lower IDT electrode 42 with respect to the upper electrode 31 and the lower electrode 32 of the resonator 30 is the same as or similar to that in the first example embodiment described above. Thus, redundant description thereof is omitted.

Specifically, in a capacitor 40A, the plurality of first electrode fingers 43A of the upper IDT electrode 41 and the plurality of fourth electrode fingers 44B of the lower IDT electrode 42 are opposed to one another with the piezoelectric layer 20 interposed therebetween in the Z-direction. The plurality of second electrode fingers 44A of the upper IDT electrode 41 and the plurality of third electrode fingers 43B of the lower IDT electrode 42 are opposed to one another with the piezoelectric layer 20 interposed therebetween in the Z-direction.

In the present example embodiment, the plurality of first electrode fingers 43A of the upper IDT electrode 41 overlap the plurality of fourth electrode fingers 44B of the lower IDT electrode 42 and extend in the same direction as the extending direction of the plurality of fourth electrode fingers 44B. The plurality of second electrode fingers 44A of the upper IDT electrode 41 overlap the plurality of third electrode fingers 43B of the lower IDT electrode 42 and extend in the same direction as the extending direction of the plurality of third electrode fingers 43B.

Different electric potentials are supplied to the plurality of first electrode fingers 43A of the upper IDT electrode 41 and the plurality of fourth electrode fingers 44B of the lower IDT electrode 42 opposed to one another in the Z-direction. Moreover, different electric potentials are supplied to the plurality of second electrode fingers 44A of the upper IDT electrode 41 and the plurality of third electrode fingers 43B of the lower IDT electrode 42 opposed to one another in the Z-direction.

Moreover, the plurality of first electrode fingers 43A of the upper IDT electrode 41 and the plurality of third electrode fingers 43B of the lower IDT electrode 42 electrically connected to one another and to which the same electric potential is supplied are disposed at positions not overlapping one another. Furthermore, the plurality of second electrode fingers 44A of the upper IDT electrode 41 and the plurality of fourth electrode fingers 44B of the lower IDT electrode 42 electrically connected to one another and to which the same electric potential is supplied are disposed at positions not overlapping one another.

FIG. 5 is an explanatory diagram illustrating capacitances generated in a capacitor according to the second example embodiment. As illustrated in FIG. 5, in the capacitor 40A, a capacitance Cz3 is generated between the first electrode finger 43A of the upper IDT electrode 41 and the fourth electrode finger 44B of the lower IDT electrode 42 opposed to one another with the piezoelectric layer 20 interposed therebetween in the Z-direction. Similarly, a capacitance Cz4 is generated between the second electrode finger 44A of the upper IDT electrode 41 and the third electrode finger 43B of the lower IDT electrode 42 opposed to one another with the piezoelectric layer 20 interposed therebetween in the Z-direction.

In the second example embodiment, a distance between the first electrode finger 43A of the upper IDT electrode 41 and the fourth electrode finger 44B of the lower IDT electrode 42 is shorter than that in the first example embodiment described above. Moreover, a distance between the second electrode finger 44A of the upper IDT electrode 41 and the third electrode finger 43B of the lower IDT electrode 42 is shorter than that in the first example embodiment described above. Therefore, the capacitances Cz3 and Cz4 of the capacitor 40A are larger than the capacitances Cz1 and Cz2 of the capacitor 40 in the first example embodiment.

Also in the second example embodiment, the capacitance Cx1 is generated between the first electrode finger 43A and the second electrode finger 44A of the upper IDT electrode 41 adjacent to one another in the X-direction in the same layer. Moreover, the capacitance Cx2 is generated between the third electrode finger 43B and the fourth electrode finger 44B of the lower IDT electrode 42 adjacent to one another in the X-direction in the same layer. The capacitances Cx1 and Cx2 are the same or substantially the same as those in the first example embodiment.

Therefore, the acoustic wave device 10A according to the second example embodiment can increase the capacitance of the capacitor 40A as a whole as compared with the first example embodiment.

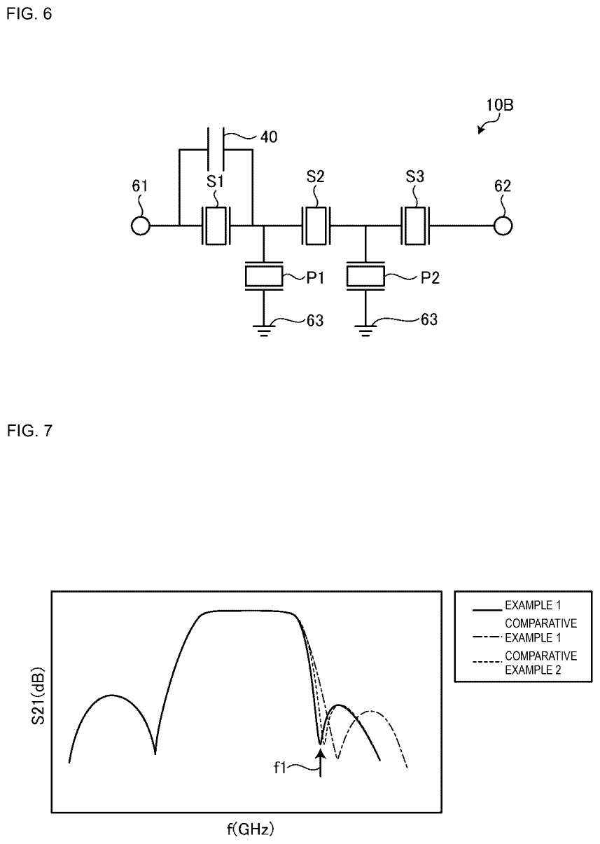

FIG. 6 is a circuit diagram illustrating an acoustic wave device according to a third example embodiment of the present invention. As illustrated in FIG. 6, an acoustic wave device 10B according to the third example embodiment is different from that of each example embodiment described above in that the acoustic wave device 10B includes a plurality of resonators.

In more detail, the acoustic wave device 10B includes a plurality of series arm resonators S1, S2, and S3, a plurality of parallel arm resonators P1 and P2, and the capacitor 40. The plurality of series arm resonators S1, S2, and S3 are each connected on a signal path between an input terminal 61 and an output terminal 62 in series. The plurality of parallel arm resonators P1 and P2 are each connected between a node on the signal path connecting the input terminal 61 and the output terminal 62 and a reference potential 63 in parallel. The acoustic wave device 10B according to the third example embodiment is a ladder filter.

One terminal of the plurality of series arm resonators S1, S2, and S3 connected in series is electrically connected to the input terminal 61 and the other terminal thereof is electrically connected to the output terminal 62. One terminal of the parallel arm resonator P1 is electrically connected to a node on a signal path connecting the series arm resonator S1 and the series arm resonator S2, and the other terminal thereof is electrically connected to the reference potential 63. One terminal of the parallel arm resonator P2 is electrically connected to a node on a signal path connecting the series arm resonator S2 and the series arm resonator S3, and the other terminal thereof is electrically connected to the reference potential 63.

In the present example embodiment, the reference potential 63 is, for example, a ground potential. However, the reference potential 63 is not limited to the ground potential, and may be an electric potential different therefrom.

The capacitor 40 is connected to the series arm resonator S1 in parallel. That is, the capacitor 40 is connected in parallel with the series arm resonator S1 and is connected between the input terminal 61 and the output terminal 62 in series. In more detail, one end of the capacitor 40 is electrically connected to a node on a signal path connecting the input terminal 61 and the series arm resonator S1. The other end of the capacitor 40 is electrically connected to a node on the signal path connecting the series arm resonator S1 and the series arm resonator S2.

FIG. 7 is a graph illustrating bandpass characteristics of acoustic wave devices according to Example 1 of an example embodiment of the present invention and Comparative Examples 1 and 2. The acoustic wave device according to Example 1 illustrated in FIG. 7 is a ladder filter illustrated in FIG. 6 and includes the capacitor 40 connected to the series arm resonator S1. The acoustic wave device according to Comparative Example 1 is a ladder filter similar to that of Example 1, but is different from Example 1 in that the capacitor 40 is not provided. The acoustic wave device according to Comparative Example 2 includes a capacitor connected to the series arm resonator S1 similarly to Example 1, but is different from Example 1 in that the capacitor includes only one of the upper IDT electrode 41 and the lower IDT electrode 42.

A vertical axis of the graph in FIG. 7 indicates a level (dB) of an S parameter S21. A horizontal axis of the graph in FIG. 7 indicates a frequency (GHz).

As illustrated in FIG. 7, bandpass characteristics of the acoustic wave device according to each of Example 1 and Comparative Examples 1 and 2 include two attenuation poles. The acoustic wave device according to Example 1 includes the capacitor 40 connected to the series arm resonator S1. Therefore, as compared with Comparative Example 1 without the capacitor 40, one of the two attenuation poles at the higher frequency side, which is indicated by an arrow f1, can be shifted to the lower frequency side.

Moreover, in the acoustic wave device according to Example 1, the capacitor 40 includes the upper IDT electrode 41 and the lower IDT electrode 42. Therefore, as compared with Comparative Example 2 including only one of the upper IDT electrode 41 and the lower IDT electrode 42, a larger capacitance is generated. Thus, as compared with Comparative Example 2, the acoustic wave device according to Example 1 can shift the attenuation pole at the higher frequency side, which is indicated by the arrow f1, to the lower frequency side.

Therefore, it is shown that the acoustic wave device according to Example 1 can adjust the bandpass characteristics more favorably as compared with Comparative Examples 1 and 2.

The configuration of the acoustic wave device 10B illustrated in FIG. 6 is merely an illustration and can be changed as appropriate. For example, the capacitor 40A of the second example embodiment may be provided instead of the capacitor 40. Moreover, the numbers and connecting configurations of the plurality of series arm resonators S1, S2, and S3 and the plurality of parallel arm resonators P1 and P2 can be changed as appropriate in accordance with bandpass characteristics required for the acoustic wave device 10B.

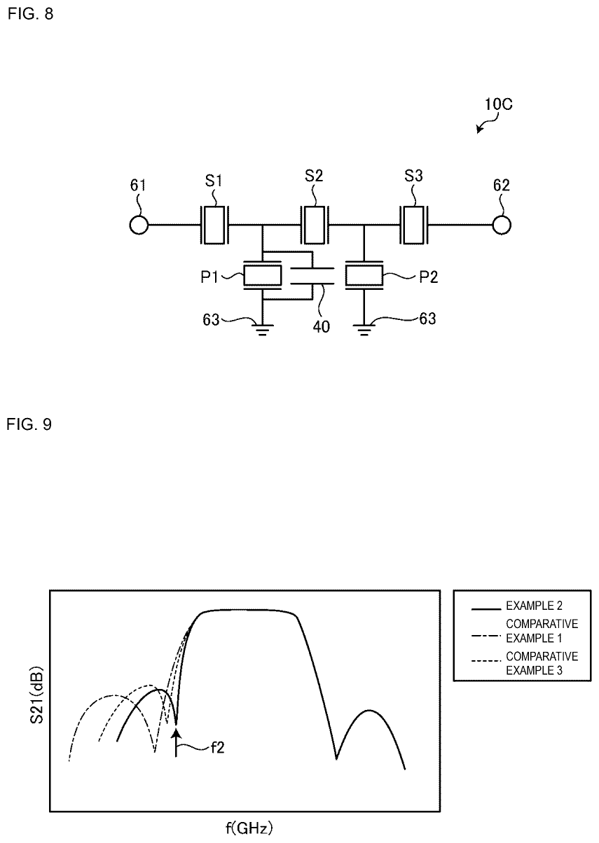

FIG. 8 is a circuit diagram illustrating an acoustic wave device according to a fourth example embodiment of the present invention. As illustrated in FIG. 8, an acoustic wave device 10C according to the fourth example embodiment is different from that of the third example embodiment described above in that the capacitor 40 is connected to the parallel arm resonator P1.

The capacitor 40 is connected in parallel with the parallel arm resonator P1. One terminal of the capacitor 40 is connected to a signal path between the input terminal 61 and the output terminal 62. More specifically, the one terminal of the capacitor 40 is electrically connected to a node on a signal path connecting the series arm resonator S1 and the series arm resonator S2. The other terminal of the capacitor 40 is electrically connected to the reference potential 63.

The configurations of the plurality of series arm resonators S1, S2, and S3 and the plurality of parallel arm resonators P1 and P2 are the same as or similar to those of the third example embodiment described above. Thus, redundant description thereof is omitted.

FIG. 9 is a graph illustrating bandpass characteristics of acoustic wave devices according to Example 2 of an example embodiment of the present invention and Comparative Examples 1 and 3. The acoustic wave device according to Example 2 illustrated in FIG. 9 is a ladder filter illustrated in FIG. 8 and includes the capacitor 40 connected to the parallel arm resonator P1. The acoustic wave device according to Comparative Example 3 includes a capacitor connected to the parallel arm resonator P1 similarly to Example 2, but is different from Example 2 in that the capacitor includes only one of the upper IDT electrode 41 and the lower IDT electrode 42.

As illustrated in FIG. 9, the acoustic wave device according to Example 2 includes the capacitor 40 connected to the parallel arm resonator P1. Therefore, as compared with Comparative Example 1 without the capacitor 40, one of the two attenuation poles at the lower frequency side, which is indicated by an arrow f2, can be shifted to the higher frequency side.

Moreover, in the acoustic wave device according to Example 2, the capacitor 40 includes the upper IDT electrode 41 and the lower IDT electrode 42. Therefore, as compared with Comparative Example 3 including only one of the upper IDT electrode 41 and the lower IDT electrode 42, a larger capacitance is generated. Thus, the acoustic wave device according to Example 2 can shift the attenuation pole at the lower frequency side, which is indicated by the arrow f2, to the higher frequency side.

Therefore, it is shown that the acoustic wave device according to Example 2 can adjust the bandpass characteristics more favorably as compared with Comparative Examples 1 and 3.

The acoustic wave device 10C is not limited to a configuration illustrated in FIG. 8, but, for example, the capacitor 40A of the second example embodiment may be provided instead of the capacitor 40. Moreover, the configuration of the fourth example embodiment can be combined with the configuration of the third example embodiment. That is, the acoustic wave device 10C may include a plurality of capacitors 40 including the capacitor 40 connected to the series arm resonator S1 and the capacitor 40 connected to the parallel arm resonator P1.

The example embodiments described above are provided to facilitate understanding of the present invention, and are not to limit an interpretation of the present invention. Example embodiments of the present invention may be changed or modified without departing from the scope and spirit thereof and also includes equivalents thereof.

While example embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. An acoustic wave device comprising:
a resonator including:
a piezoelectric layer including a first main surface and a second main surface opposite to the first main surface;
an upper electrode on the first main surface of the piezoelectric layer; and
a lower electrode on the second main surface of the piezoelectric layer; and
a capacitor including:
an upper interdigital transducer (IDT) electrode on the first main surface of the piezoelectric layer; and
a lower IDT electrode on the second main surface of the piezoelectric layer; wherein
the capacitor is connected in parallel with the resonator; and
the upper IDT electrode and the lower IDT electrode of the capacitor are electrically connected to one another.

2. The acoustic wave device according to claim 1, wherein
each of the upper IDT electrode and the lower IDT electrode includes a plurality of electrode fingers arranged in a predetermined direction;
the plurality of electrode fingers of the upper IDT electrode are opposed to the plurality of electrode fingers of the lower IDT electrode with the piezoelectric layer interposed therebetween; and
a same electric potential is supplied to an electrode finger of the upper IDT electrode and an electrode finger of the lower IDT electrode opposed to one another with the piezoelectric layer interposed therebetween.

3. The acoustic wave device according to claim 1, wherein
each of the upper IDT electrode and the lower IDT electrode includes a plurality of electrode fingers arranged in a predetermined direction;
the plurality of electrode fingers of the upper IDT electrode are opposed to the plurality of electrode fingers of the lower IDT electrode with the piezoelectric layer interposed therebetween; and
different electric potentials are supplied to an electrode finger of the upper IDT electrode and an electrode finger of the lower IDT electrode opposed to one another with the piezoelectric layer interposed therebetween.

4. The acoustic wave device according to claim 1, wherein
the upper IDT electrode includes a plurality of first electrode fingers and a plurality of second electrode fingers arranged in an alternating manner in a predetermined direction;
the lower IDT electrode includes a plurality of third electrode fingers and a plurality of fourth electrode fingers arranged in an alternating manner in the predetermined direction;
the plurality of first electrode fingers of the upper IDT electrode and the plurality of third electrode fingers of the lower IDT electrode are electrically connected to one another through a first via penetrating the piezoelectric layer; and
the plurality of second electrode fingers of the upper IDT electrode and the plurality of fourth electrode fingers of the lower IDT electrode are electrically connected to one another through a second via penetrating the piezoelectric layer.

5. The acoustic wave device according to claim 4, wherein
the plurality of first electrode fingers of the upper IDT electrode and the plurality of third electrode fingers of the lower IDT electrode are electrically connected to one of the upper electrode and the lower electrode of the resonator; and
the plurality of second electrode fingers of the upper IDT electrode and the plurality of fourth electrode fingers of the lower IDT electrode are electrically connected to another one of the upper electrode and the lower electrode of the resonator.

6. The acoustic wave device according to claim 1, further comprising:
a plurality of the resonators, wherein
the plurality of resonators include a series arm resonator and a parallel arm resonator;
the series arm resonator is connected between an input terminal and an output terminal in series;
the parallel arm resonator is connected between a signal path between the input terminal and the output terminal and a reference potential in parallel; and
the capacitor is connected in parallel with the series arm resonator and is connected between the input terminal and the output terminal in series.

7. The acoustic wave device according to claim 1, further comprising:
a plurality of the resonators; wherein
the plurality of resonators include a series arm resonator and a parallel arm resonator;
the series arm resonator is connected between an input terminal and an output terminal in series;
the parallel arm resonator is connected between a signal path between the input terminal and the output terminal and a reference potential in parallel; and
the capacitor is connected in parallel with the parallel arm resonator, one terminal of the capacitor is connected to the signal path between the input terminal and the output terminal, and another terminal of the capacitor is connected to the reference potential.

8. The acoustic wave device according to claim 1, wherein
the piezoelectric layer includes a single crystal of lithium niobate or lithium tantalate.

9. The acoustic wave device according to claim 1, wherein the resonator is configured to utilize a bulk wave.

10. The acoustic wave device according to claim 1, further comprising a support opposed to the second main surface of the piezoelectric layer.

11. The acoustic wave device according to claim 10, wherein the support includes a support substrate and an insulating layer provided between the support substrate and the piezoelectric layer.

12. The acoustic wave device according to claim 11, wherein the support substrate includes silicon or quartz.

13. The acoustic wave device according to claim 11, wherein the insulating layer includes silicon oxide.

14. The acoustic wave device according to claim 1, wherein the support includes a cavity portion opposed to the second main surface of the piezoelectric layer.

15. The acoustic wave device according to claim 1, wherein a thickness of the piezoelectric layer is about 1 μm or less.

16. The acoustic wave device according to claim 1, wherein each of the upper and lower electrodes includes aluminum, platinum, copper, tungsten, or molybdenum, or an alloy including at least one of aluminum, platinum, copper, tungsten, or molybdenum.
